(19) United States
(12) Patent Application Publication
(10) Pub. No.: US 2024/0057423 A1
(43) Pub. Date: Feb. 15, 2024

(54) DISPLAY PANEL AND DISPLAY DEVICE

(71) Applicants: CHENGDU BOE OPTOELECTRONICS TECHNOLOGY CO., LTD., Sichuan (CN); BOE TECHNOLOGY GROUP CO., LTD., Beijing (CN)

(72) Inventors: Yingchang GAO, Beijing (CN); Xilei CAO, Beijing (CN); Yangpeng WANG, Beijing (CN); Xucong WANG, Beijing (CN); Zhenhua ZHANG, Beijing (CN)

(73) Assignees: CHENGDU BOE OPTOELECTRONICS TECHNOLOGY CO., LTD., Sichuan (CN); BOE TECHNOLOGY GROUP CO., LTD., Beijing (CN)

(21) Appl. No.: 18/037,269

(22) PCT Filed: Mar. 10, 2022
(86) PCT No.: PCT/CN2022/080142

§ 371 Date: May 16, 2023

(30) Foreign Application Priority Data
Jun. 22, 2021 (CN) 202110694228.5

(51) Int. Cl. H10K 59/35

(52) U.S. Cl. CPC H10K 59/353; H10K 59/352

(57) ABSTRACT

A display panel includes pixels arranged in rows and columns; each pixel includes a first sub-pixel configured to display a first color, a second sub-pixel configured to display a second color, and a third sub-pixel configured to display a third color; all sub-pixels included in the plurality of pixels are arranged in columns; in an odd-numbered column of sub-pixels, first sub-pixels and second sub-pixels are alternately arranged; in an even-numbered column of sub-pixels, third sub-pixels are sequentially arranged, for a first sub-pixel and a second sub-pixel of a same pixel, along a column direction, a border of the first sub-pixel proximate to the second sub-pixel is a first border, and a border of the second sub-pixel proximate to the first sub-pixel is a second border, and distances from at least two points on the first border to the second border along the column direction are not equal.

### CROSS-REFERENCE TO RELATED APPLICATIONS

This application is a national phase entry under 35 USC 371 of International Patent Application No. PCT/CN2022/080142, filed on Mar. 10, 2022, which claims priority to Chinese Patent Application No. 202110694228.5, filed on Jun. 22, 2021, which are incorporated herein by reference in their entirety.

### TECHNICAL FIELD

The present disclosure relates to the field of display technologies, and in particular, to a display panel and a display device.

### BACKGROUND

Organic light-emitting diode (OLED) display panels have gradually become one of mainstreams in the display field due to their excellent performance such as low power consumption, high color saturation, wide viewing angle, small thickness, and flexibility.

The display panel may include a plurality of pixels, and each pixel may further include at least one sub-pixel. The arrangement of the plurality of sub-pixels in the display panel is different, and the display effect of the display panel is also different.

### SUMMARY

In one aspect, a display panel is provided. The display panel includes a plurality of pixels arranged in a plurality of rows and a plurality of columns; each pixel includes a first sub-pixel configured to display a first color, a second sub-pixel configured to display a second color, and a third sub-pixel configured to display a third color; all sub-pixels included in the plurality of pixels are arranged in a plurality of columns; in an odd-numbered column of sub-pixels, first sub-pixels and second sub-pixels are alternately arranged; in an even-numbered column of sub-pixels, third sub-pixels are sequentially arranged; for a first sub-pixel and a second sub-pixel of a same pixel, along a column direction, a border of the first sub-pixel proximate to the second sub-pixel is a first border, and a border of the second sub-pixel proximate to the first sub-pixel is a second border; and distances from at least two points on the first border to the second border along the column direction are not equal.

In some embodiments, for the first sub-pixel and the second sub-pixel of the same pixel, along the column direction, a border of the first sub-pixel away from the second sub-pixel is a third border, and a border of the second sub-pixel away from the first sub-pixel is a fourth border; and distance from at least two points on the third border to a fourth border of a second sub-pixel of an adjacent pixel along the column direction are not equal.

In some embodiments, in a row direction, a distance between the first border and the second border along the column direction increases first and then decreases; and/or, in the row direction, a distance between the third border and the fourth border of the second sub-pixel of the adjacent pixel along the column direction increases first and then decreases.

In some embodiments, in a row direction, a distance between the first border and the second border along the column direction decreases first and then increases; and/or, in the row direction, a distance between the third border and the fourth border of the second sub-pixel of the adjacent pixel along the column direction decreases first and then increases.

In some embodiments, at least one of the first border and the second border is in a shape of an arc; and/or, at least one of the third border and the fourth border is in a shape of an arc.

In some embodiments, a radius of an arc greater than or equal to a half of a size, in the row direction, of a sub-pixel to which the arc belongs; and the radius of the arc is less than or equal to a maximum size, in the column direction, of the sub-pixel to which the arc belongs.

In some embodiments, at least one of the first border and the second border includes a first broken line segment and a second broken line segment that are connected to each other; the first broken line segment and the second broken line segment constitute a first included angle; and the first included angle is greater than or equal to 90 degrees and less than or equal to 180 degrees; and/or, at least one of the third border and the fourth border includes a third broken line segment and a fourth broken line segment that are connected to each other; the third broken line segment and the fourth broken line segment constitute a second included angle; and the second included angle is greater than or equal to 90 degrees and less than or equal to 180 degrees.

In some embodiments, at least one of the first border and the third border is recessed towards an interior of the first sub-pixel; and/or, at least one of the second border and the fourth border of the second sub-pixel is recessed towards an interior of the second sub-pixel.

In some embodiments, at least one of the first border and the third border protrudes towards an outside of the first sub-pixel; and/or; at least one of the second border and the fourth border of the second sub-pixel protrudes towards an outside of the second sub-pixel.

In some embodiments, at least one of the first border, the second border, the third border, and the fourth border is a broken line, and the broken line includes at least three broken line segments connected in sequence.

In some embodiments, the first border and the second border are symmetric with respect to a first reference line extending along a row direction; and/or, the third border and the fourth border are symmetrical with respect to another first reference line extending along the row direction.

In some embodiments, at least one of the first border, the second border, the third border, and the fourth border is an axisymmetric pattern whose symmetry axis extends along the column direction.

In some embodiments, in the same pixel, the first sub-pixel includes a fifth border extending along the column direction and proximate to the third sub-pixel, and the second sub-pixel includes a sixth border extending along the column direction and proximate to the third sub-pixel; the third sub-pixel includes a seventh border extending along the column direction and proximate to the first sub-pixel or the second sub-pixel; in the same pixel, the seventh border is at least partially directly opposite to at least one of the fifth border and the sixth border in a row direction.

In some embodiments, the third sub-pixel includes at least one eighth border extending along a row direction, and the at least one eighth border is a straight line segment.

In some embodiments, a distance between two adjacent third sub-pixels along the column direction is equal.

In some embodiments, the distance between the two adjacent third sub-pixels is greater than a minimum distance between a first sub-pixel and a second sub-pixel that are adjacent in a same column of sub-pixels.

In some embodiments, in a same column of sub-pixels, along the column direction, distances between the third sub-pixel and two third sub-pixels adjacent to the third sub-pixel are a first distance and a second distance, respectively; the first distance is less than the second distance; the first distance is less than a minimum distance between a first sub-pixel and a second sub-pixel that are adjacent in the same column of sub-pixels, and the second distance is greater than the minimum distance between the first sub-pixel and the second sub-pixel that are adjacent in the same column of sub-pixels.

In some embodiments, two adjacent third sub-pixels with a distance of the first distance along the column direction share one light-emitting layer.

In some embodiments, along the column direction, a border of the third sub-pixel proximate to another third sub-pixel adjacent to the third sub-pixel is a ninth border; and distances from at least two points on the ninth border to another ninth border adjacent to the ninth border along the column direction are not equal.

In another aspect, a display device is provided. The display device includes the display panel according to any one of the above embodiments.

### BRIEF DESCRIPTION OF THE DRAWINGS

In order to describe technical solutions in the present disclosure more clearly, the accompanying drawings to be used in some embodiments of the present disclosure will be introduced briefly. However, the accompanying drawings to be described below are merely some embodiments of the present disclosure, and a person of ordinary skill in the art can obtain other drawings according to those drawings. In addition, the accompanying drawings in the following description may be regarded as schematic diagrams, but are not limitations on actual sizes of products, actual processes of methods and actual timings of signals involved in the embodiments of the present disclosure.

FIG. 1 is a top view of a display panel, in accordance with some embodiments;

FIG. 2 is a structural diagram of a pixel, in accordance with some embodiments;

FIG. 3 is a sectional view of a display panel, in accordance with some embodiments;

FIG. 4 is a top view of another display panel, in accordance with some embodiments;

FIG. 5 is a structural diagram of another pixel, in accordance with some embodiments;

FIG. 6A is a top view of yet another display panel, in accordance with some embodiments;

FIG. 6B is a structural diagram of yet another pixel, in accordance with some embodiments;

FIG. 6C is a top view of yet another display panel, in accordance with some embodiments;

FIG. 6D is a structural diagram of yet another pixel, in accordance with some embodiments;

FIG. 6E is a top view of yet another display panel, in accordance with some embodiments;

FIG. 6F is a structural diagram of yet another pixel, in accordance with some embodiments;

FIG. 6G is a structural diagram of yet another pixel, in accordance with some embodiments;

FIG. 7A is a top view of yet another display panel, in accordance with some embodiments;

FIG. 7B is a top view of yet another display panel, in accordance with some embodiments;

FIG. 7C is a top view of yet another display panel, in accordance with some embodiments;

FIG. 7D is a top view of yet another display panel, in accordance with some embodiments;

FIG. 8A is a structural diagram of a sub-pixel, in accordance with some embodiments;

FIG. 8B is a structural diagram of another sub-pixel, in accordance with some embodiments;

FIG. 8C is a structural diagram of yet another sub-pixel, in accordance with some embodiments;

FIG. 9A is a top view of yet another display panel, in accordance with some embodiments;

FIG. 9B is a top view of yet another display panel, in accordance with some embodiments;

FIG. 9C is a top view of yet another display panel, in accordance with some embodiments;

FIG. 10 is a top view of yet another display panel, in accordance with some embodiments;

FIG. 11 is a structural diagram of yet another pixel, in accordance with some embodiments;

FIG. 12 is a structural diagram of a display panel, in accordance with some embodiments;

FIG. 13 is a structural diagram of another display panel, in accordance with some embodiments;

FIG. 14 is a structural diagram of yet another pixel, in accordance with some embodiments;

FIG. 15 is a top view of yet another display panel, in accordance with some embodiments;

FIG. 16 is a top view of yet another display panel, in accordance with some embodiments;

FIG. 17 is a top view of yet another display panel, in accordance with some embodiments; and

FIG. 18 is a structural diagram of a display device, in accordance with some embodiments.

### DETAILED DESCRIPTION

The technical solutions in some embodiments of the present disclosure will be described clearly and completely below with reference to the accompanying drawings. However, the described embodiments are merely some but not all of the embodiments of the present disclosure. All other embodiments obtained by a person of ordinary skill in the art based on the embodiments of the present disclosure shall be included in the protection scope of the present disclosure.

Unless the context requires otherwise, throughout the description and the claims, the term “comprise” and other forms thereof such as the third-person singular form “comprises” and the present participle form “comprising” are construed in an open and inclusive meaning, i.e., “including, but not limited to”. In the description of the specification, the terms such as “one embodiment,” “some embodiments,” “exemplary embodiments,” “example,” “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, specific features, structures, materials or characteristics may be included in any one or more embodiments or examples in any suitable manner.

Hereinafter, the terms such as “first” and “second” are used for descriptive purposes only, but are not to be construed as indicating or implying the relative importance or implicitly indicating the number of indicated technical features. Thus, a feature defined with the term such as “first” or “second” may explicitly or implicitly include one or more features. In the description of the embodiments of the present disclosure, the terms “a plurality of”, “the plurality of” and “multiple” each mean two or more unless otherwise specified.

The phrase “at least one of A, B and C” has the same meaning as the phrase “at least one of A, B or C”, and they both include following combinations of A, B and C: only A, only B, only C, a combination of A and B, a combination of A and C, a combination of to B and C, and a combination of A, B and C.

The phrase “A and/or B” includes the following three combinations: only A, only B, and a combination of A and B.

The use of the phrase “applicable to” or “configured to” herein is meant an open and inclusive expression, which does not exclude devices that are applicable to or configured to perform additional tasks or steps.

The term such as “about” or “approximately” as used herein includes a stated value and an average value within an acceptable range of deviation of a particular value determined by a person of ordinary skill in the art, considering measurement in question and errors associated with measurement of a particular quantity (i.e., limitations of a measurement system).

The term such as “parallel,” “perpendicular,” or “equal” as used herein includes a stated case and a case similar to the stated case. The similar case is within an acceptable range of deviation, and the acceptable range of deviation is determined by a person of ordinary skill in the art in view of measurement in question and errors associated with measurement of a particular quantity (i.e., limitations of a measurement system). For example, the term “parallel” includes absolute parallelism and approximate parallelism, where an acceptable range of deviation of the approximate parallelism may be, for example, a deviation within 5 degrees; the term “perpendicular” includes absolute perpendicularity and approximate perpendicularity, where an acceptable range of deviation of the approximate perpendicularity may also be, for example, a deviation within degrees. The term “equal” includes absolute equality and approximate equality, where an acceptable range of deviation of the approximate equality may be, for example, a difference between two equals of less than or equal to 5% of either of the two equals.

Exemplary embodiments are described herein with reference to sectional views and/or plan views as idealized exemplary drawings. In the accompanying drawings, thicknesses of layers and areas of regions are enlarged for clarity. Thus, variations in shapes with respect to the accompanying drawings due to, for example, manufacturing technologies and/or tolerances may be envisaged. Therefore, the exemplary embodiments should not be construed as being limited to the shapes of the regions shown herein, but as including shape deviations due to, for example, manufacturing. For example, an etched region shown to have a rectangular shape generally has a feature of being curved. Therefore, the regions shown in the accompanying drawings are schematic in nature, and their shapes are not intended to show actual shapes of regions in an apparatus, and are not intended to limit the scope of the exemplary embodiments.

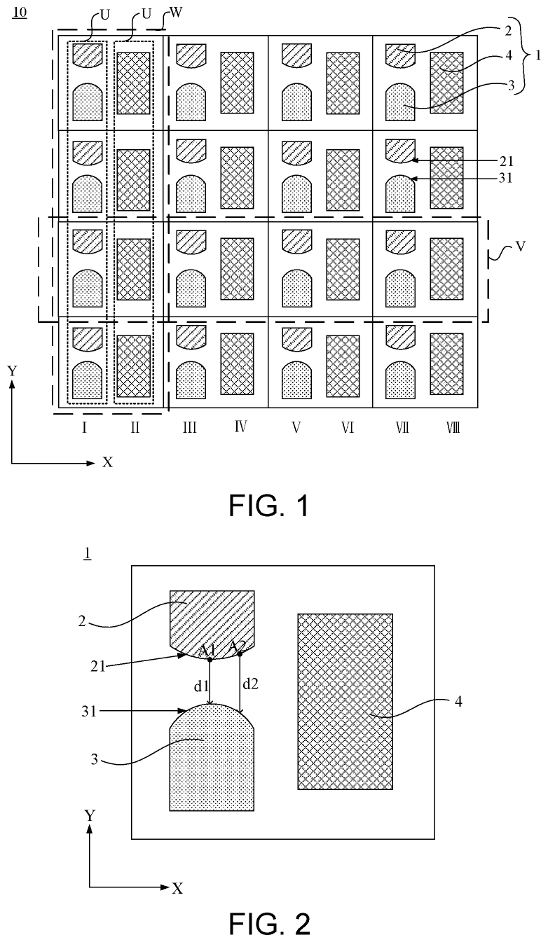

As shown in FIGS. 1 and 2, some embodiments of the present disclosure provide a display panel 10 including a plurality of pixels 1 arranged in a plurality of rows and a plurality of columns. For example, in FIG. 1, the dashed box V indicates one row of pixels 1, and the dashed box W indicates one column of pixels 1. Each pixel 1 includes a first sub-pixel 2 configured to display a first color, a second sub-pixel 3 configured to display a second color, and a third sub-pixel 4 configured to display a third color.

The first color, the second color and the third color are three primary colors. For example, the first color is red, the second color is green, and the third color is blue. However, the first color, the second color and the third color in the embodiments of the present disclosure are not limited thereto.

FIG. 1 shows 4×4 pixels 1 of the display panel 10. The number of the pixels 1 included in the display panel 10 is not limited in the present disclosure. For example, the display panel 10 may include 2340×1080 pixels 1.

All sub-pixels included in the plurality of pixels 1 are arranged in a plurality of columns. For example, the dashed box U in FIG. 1 indicates one column of sub-pixels. For example, the plurality of columns of sub-pixels are sequentially numbered as I to VIII in an order from left to right. In an odd-numbered column of sub-pixels, first sub-pixels 2 and second sub-pixels 3 are alternately arranged. FIG. 1 shows I, III, V and VII columns of sub-pixels. In an even-numbered column of sub-pixels, third sub-pixels 4 are sequentially arranged. FIG. 1 shows II, IV, VI and VIII columns of sub-pixels.

For a first sub-pixel 2 and a second sub-pixel 3 of the same pixel 1, along a column direction Y, a border of the first sub-pixel 2 proximate to the second sub-pixel 3 is a first border 21, and a border of the second sub-pixel 3 proximate to the first sub-pixel 2 is a second border 31. Distances from at least two points on the first border 21 to the second border 31 along the column direction Y are not equal.

As shown in FIG. 2, the description that “distances from at least two points on the first border 21 to the second border 31 along the column direction Y are not equal” may be that, for example, there are two points A1 and A2 on the first border 21, a distance between the point A1 and the second border 31 along the column direction Y is d1, and a distance between the point A2 and the second border 31 along the column direction Y is d2, and values of d1 and d2 are not equal.

In some embodiments of the present disclosure, each pixel 1 includes the first sub-pixel 2 for displaying the first color, the second sub-pixel 3 for displaying the second color, and the third sub-pixel 4 for displaying the third color, so that each pixel 1 can display a plurality of colors. Therefore, the display panel 10 has high image display accuracy, good clarity, and good display effect. Moreover, the distances from the at least two points on the first border 21 to the second border 31 along the column direction Y are not equal, so that a distance between a brightness center of the first sub-pixel 2 and a brightness center of the second sub-pixel 3 may be adjusted. Therefore, a position of a brightness center of the pixel 1 is adjusted. As a result, when the display panel 10 uses the plurality of pixels 1 to display images, dark spots, jaggy lines, color edges, or other defects are not prone to occur in the displayed images.

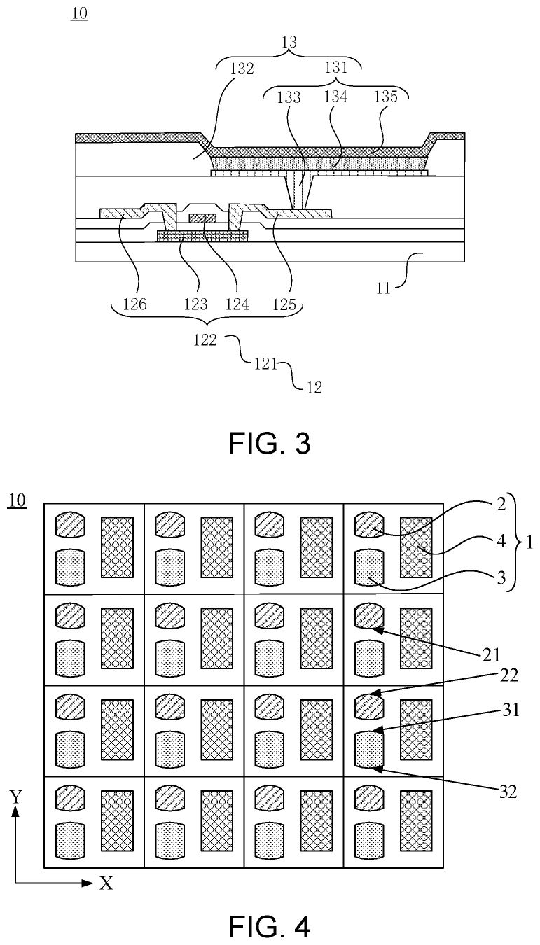

In some embodiments, as shown in FIG. 3, the display panel 10 further includes a substrate 11, a circuit structure layer 12 disposed on a side of the substrate 11, and a light-emitting device layer 13 disposed on a side of the circuit structure layer 12 away from the substrate 11. The circuit structure layer 12 includes a plurality of pixel driving circuits 121, and each of the pixel driving circuits 121 may include a plurality of thin film transistors 122 and at least one storage capacitor. The thin film transistor 122 may include a semiconductor layer pattern 123, a gate 124, a source 125, and a drain 126. The light-emitting device layer 13 may include a plurality of light-emitting devices 131 and a pixel defining layer 132, and each light-emitting device 131 may include an anode layer pattern 133, a light-emitting layer 134, and a cathode layer 135. The pixel defining layer 132 is located on a side of the anode layer 133 away from the circuit structure layer 12. The pixel defining layer 132 is provided with a plurality of openings therein. An opening corresponds to an anode layer pattern 133, and exposes at least part of the anode layer pattern 133. A light-emitting layer 134 may be located in an opening of the pixel defining layer 132.

For example, each sub-pixel includes one light-emitting device 131, and an edge of the sub-pixel may be an edge of an opening of the pixel defining layer 132.

In some embodiments, as shown in FIG. 4, for the first sub-pixel 2 and the second sub-pixel 3 of the same pixel 1, along the column direction Y, a border of the first sub-pixel 2 away from the second sub-pixel 3 is a third border 22, and a border of the second sub-pixel 3 away from the first sub-pixel 2 is a fourth border 32. Distances from at least two points on the third border 22 to a fourth border of a second sub-pixel 3 of an adjacent pixel 1 along the column direction Y are not equal.

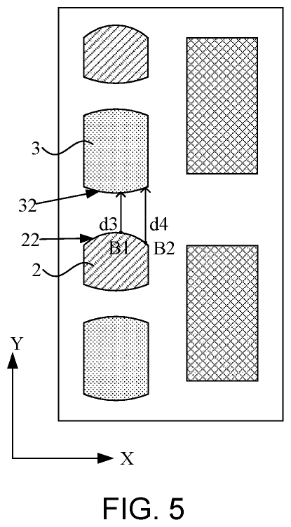

As shown in FIG. 5, the description that “distances from at least two points on the third border 22 to a fourth border of a second sub-pixel 3 of an adjacent pixel 1 along the column direction Y are not equal” may be that, for example, there may be a point B1 and a point B2 on the third border 22, a distance between the point B1 and the fourth border 32 along the column direction Y is d3, a distance between the point B2 and the fourth border 32 along the column direction Y is d4, and values of d3 and d4 are not equal.

In some embodiments of the present disclosure, since the distances from the at least two points on the third border 22 to the fourth border of the second sub-pixel 3 of the adjacent pixel 1 along the column direction Y are not equal, a position relationship between brightness centers of a first sub-pixel 2 and a second sub-pixel 3 that are located in two adjacent pixels 1 and in the same column may be adjusted. Therefore, a distance between brightness centers of the two adjacent pixels 1 in the same column is adjusted. As a result, when the display panel 10 uses the plurality of pixels 1 to display images, dark spots, jaggy lines, color edges, or other defects are not prone to occur in the displayed images.

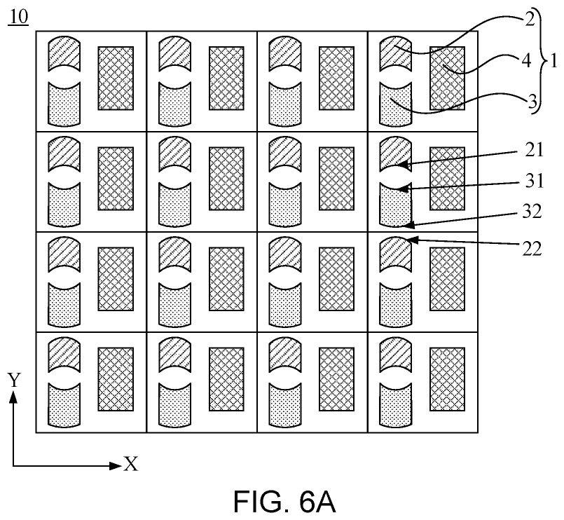

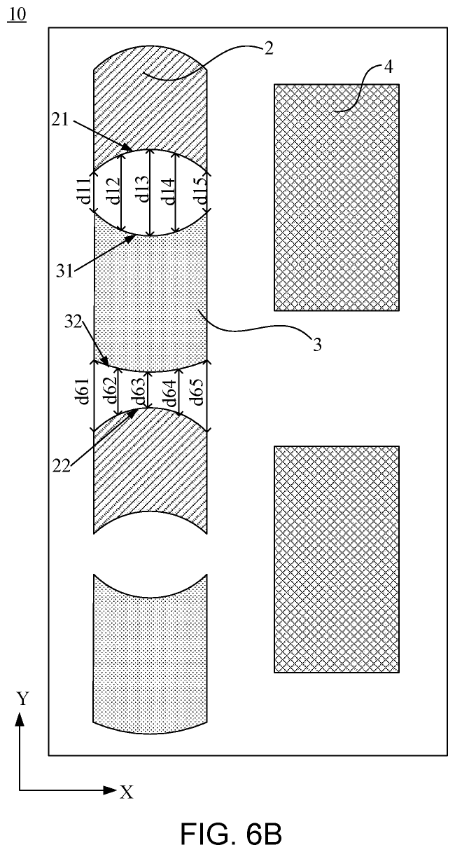

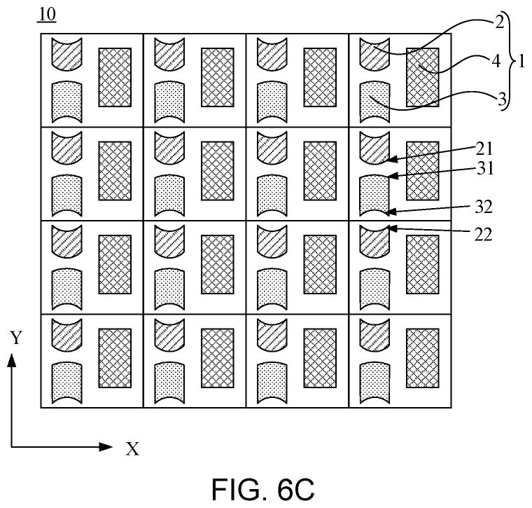

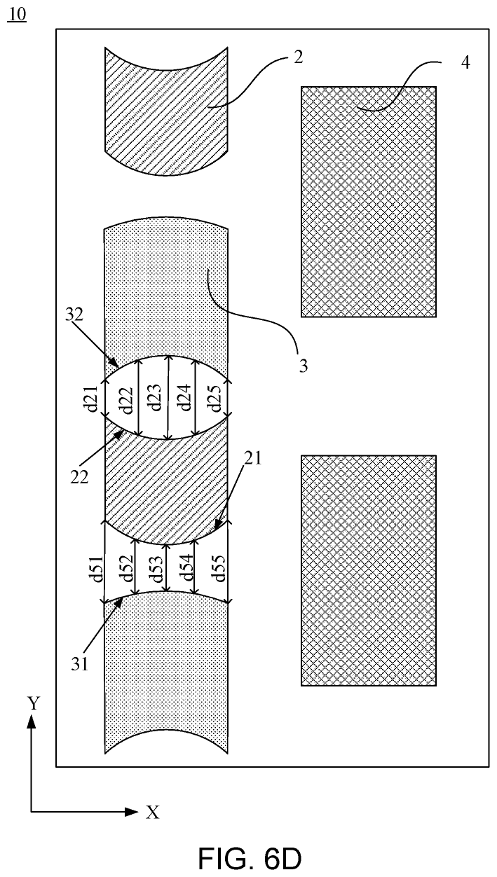

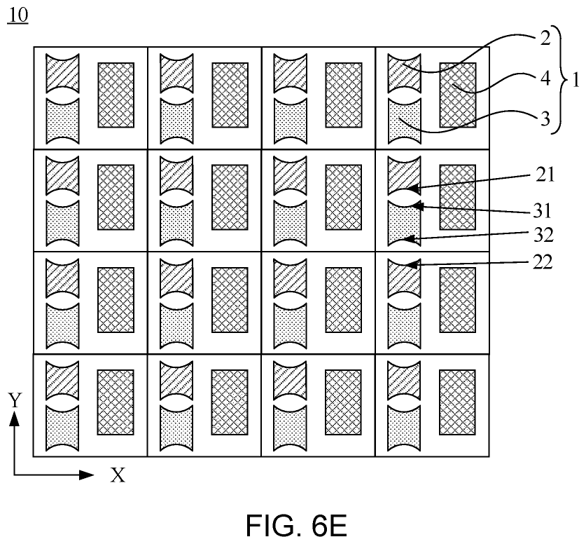

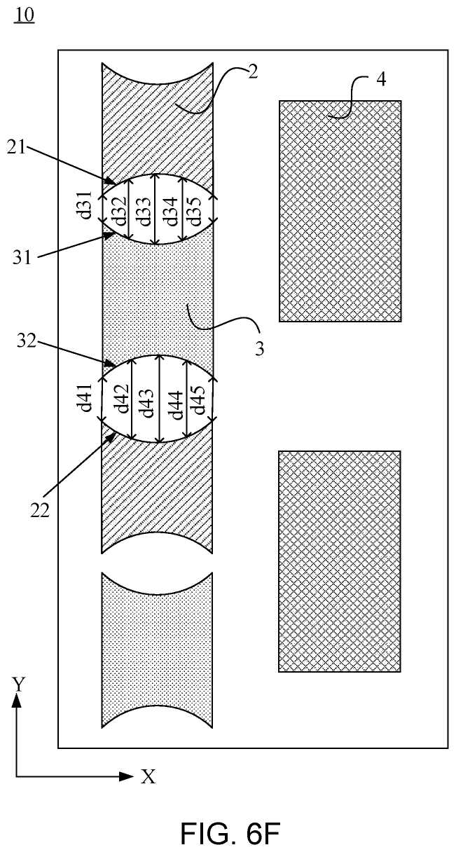

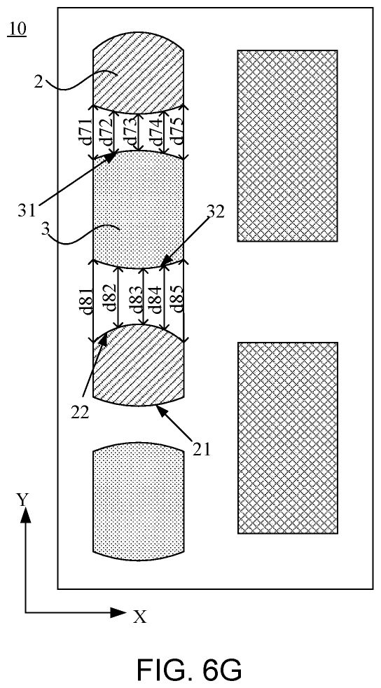

In some embodiments, as shown in FIG. 6A, in the row direction X, the distance between the first border 21 and the second border 31 along the column direction Y increases first and then decreases. For example, FIG. 6B shows five distance values between the first border 21 and the second border 31 at different positions along the column direction Y, and the five distance values are d11, d12, d13, d14 and d15, respectively; in the row direction X (for example, in an order from left to right in FIG. 6B), d11 is less than d12 and d12 is less than d13 (d11<d12<d13), and d13 is greater than d14 and d14 is greater than d15 (d13>d14>d15); that is, the five distance values increase first and then decrease.

Based on this, the variation trend of the distance between the third border 22 and to the fourth border 32 of the second sub-pixel 3 of the adjacent pixel 1 along the column direction Y is not limited in the present disclosure. As shown in FIG. 6A, the distance between the third border 22 and the fourth border 32 along the column direction Y may decrease first and then increase. Alternatively, the distance between the third border 22 and the fourth border 32 along the column direction Y may gradually decrease. Alternatively, the distance between the third border 22 and the fourth border 32 along the column direction Y may gradually increase.

In this way, in the same pixel 1, a distance between the brightness center of the first sub-pixel 2 and the brightness center of the second sub-pixel 3 is large, so that the position of the brightness center of the pixel 1 may be adjusted. Therefore, when the display panel 10 uses the plurality of pixels 1 to display images, dark spots, jaggy lines, color edges, or other defects are not prone to occur in the displayed images.

In some other embodiments, as shown in FIG. 6C, in the row direction X, the distance between the third border 22 and the fourth border 32 of the second sub-pixel 3 in the adjacent pixel 1 along the column direction Y increases first and then decreases. For example, FIG. 6D shows five distance values between the third border 22 and the fourth border 32 of the adjacent pixel 1 at different positions along the column direction and the five distance values are d21, d22, d23, d24 and d25, respectively; in the row direction X (for example, an order from left to right in FIG. 6D), d21 is less than d22 and d22 is less than d23 (d21<d22<d23), and d23 is greater than d24 and d24 is greater than d25 (d23>d24>d25); that is, the five distance values first increase and then decrease.

Based on this, the variation trend of the distance between the first border 21 and the second border 31 along the column direction Y is not limited in the present disclosure. As shown in FIG. 6C, the distance between the first border 21 and the second border 31 along the column direction Y may decrease first and then increase. Alternatively, the distance between the first border 21 and the second border 31 along the column direction Y may gradually decrease. Alternatively, the distance between the first border 21 and the second border 31 along the column direction Y may gradually increase.

In this way, a distance between the brightness center of the first sub-pixel 2 and the brightness center of the second sub-pixel 3 of the adjacent pixel 1 that is located in the same column as the first sub-pixel 2 is large, so that the distance between brightness centers of two adjacent pixels 1 may also be large. Therefore, positions of brightness centers of the plurality of pixels 1 in the display panel 10 may be adjusted. As a result, when the display panel 10 uses the plurality of pixels 1 to display images, dark spots, jaggy lines, color edges, or other defects are not prone to occur in the displayed images.

In some other embodiments, as shown in FIG. 6E, in the row direction X, the distance between the first border 21 and the second border 31 along the column direction Y increases first and then decreases; and in the row direction X, the distance between the third border 22 and the fourth border 32 of the second sub-pixel 3 of the adjacent pixel 1 along the column direction Y increases first and then decreases.

For example, FIG. 6F shows five distance values (d31, d32, d33, d34, and d35) between the first border 21 and the second border 31 at different positions along the column direction Y, and five distance values (d41, d42, d43, d44, and d45) between the third border 21 and the fourth border 32 of the second sub-pixel 3 of the adjacent pixel 1 at different positions along the column direction Y.

In the row direction X (for example, in an order from left to right in FIG. 6F), d31 is less than d32 and d32 is less than d33 (d31<d32<d33), d33 is greater than d34 and d34 is greater than d35 (d33>d34>d35), d41 is less than d42 and d42 is less than d43 (d41<d42<d43), and d43 is greater than d44 and d44 is greater than d45 (d43>d44>d45). That is, the distance values first increase and then decrease.

In this way, the distance between the brightness centers of the first sub-pixel 2 and the second sub-pixel 3 that are located in the same pixel 1 is large, and the distance between the brightness centers of adjacent first sub-pixel 2 and second sub-pixel 3 that are located in the adjacent pixels is also large, so that the brightness centers of the plurality of pixels 1 in the display panel 10 are adjusted. Therefore, when the display panel displays images, dark spots, jaggy lines, color edges, or other defects are not prone to occur in the displayed images.

In some other embodiments, as shown in FIG. BC, in the row direction X, the distance between the first border 21 and the second border 31 along the column direction Y decreases first and then increases. For example, FIG. 6D shows five distance values between the first border 21 and the second border 31 at different positions along the column direction Y, and the five distance values are d51, d52, d53, d54, and d55. In the row direction X (for example, in an order from left to right in FIG. 6D), d51 is greater than d52 and d52 is greater than d53 (d51>d52>d53), d53 is less than d54 and d54 is less than d55 (d53<d54<d55). That is, the distance values decrease first and then increase.

Based on this, the variation trend of the distance between the third border 22 and the fourth border 32 of the second sub-pixel 3 in the adjacent pixel 1 along the column direction Y is not limited in the present disclosure. As shown in FIG. 6C, the distance between the third border 22 and the fourth border 32 along the column direction Y may increase first and then decrease. Alternatively, the distance between the third border 22 and the fourth border 32 along the column direction Y may gradually decrease. Alternatively, the distance between the third border 22 and the fourth border 32 along the column direction Y may gradually increase.

In this way, the distance between the brightness centers of the first sub-pixel 2 and the second sub-pixel 3 of the same pixel 1 is small, so that the position of the brightness center of the pixel 1 is adjusted. Therefore, when the display panel 10 uses the plurality of pixels 1 to display images, dark spots, jaggy lines, color edges, or other defects are not prone to occur in the displayed images. In addition, since the distance between the brightness centers of the first sub-pixel 2 and the second sub-pixel 3 of the same pixel 1 is small, the brightness of the image displayed by the pixel 1 may be high. Thus, the display panel 10 has a good display effect.

In some other embodiments, as shown in FIG. 6A, in the row direction X, the distance between the third border 22 and the fourth border 32 of the second sub-pixel 3 of the adjacent pixel 1 along the column direction Y decreases first and then increases. For example, FIG. 6B shows five distance values between the third border 33 and the fourth border 32 of the second sub-pixel 3 of the adjacent pixel 1 at different positions along the column direction Y, and the five distance values are d61, d62, d63, d64, and d65. In the row direction X (for example, in an order from left to right in FIG. 6B), d61 is greater than d62 and d62 is greater than d63 (d61>d62>d63), and d63 is less than d64 and d64 is less than d65 (d63<d64<d65). That is, the distance values decrease first and then increase.

Based on this, the variation trend of the first border 21 and the second border 31 along the column direction Y is not limited in the present disclosure. As shown in FIG. 6A, the distance between the first border 21 and the second border 31 along the column direction Y may increase first and then decrease. Alternatively, the distance between the first border 21 and the second border 31 along the column direction Y may gradually decrease. Alternatively, the distance between the first border 21 and the second border 31 along the column direction V may gradually increase.

In this way, the distance between the brightness center of the first sub-pixel 2 and the brightness center of the second sub-pixel 3 of the adjacent pixel 1 is small, so that the positions of the brightness centers of the plurality of pixels 1 in the display panel 10 may be adjusted. Therefore, when the display panel 10 displays images, dark spots, jaggy lines, color edges or other defects are not prone to occur in the displayed images. In addition, since the distance between the brightness center of the first sub-pixel 2 and the brightness center of the second sub-pixel 3 of the adjacent pixel 1 is small, when the first sub-pixel 2 or the second sub-pixel 3 of the pixel 1 fails to emit light normally, the first sub-pixel 2 or the second sub-pixel 3 of the adjacent pixel 1 may be borrowed for display.

In some other embodiments, as shown in FIG. 4, in the row direction X, the distance between the first border 21 and the second border 31 along the column direction Y decreases first and then increases; and in the row direction X, the distance between the third border 22 and the fourth border 32 of the second sub-pixel 3 of the adjacent pixel 1 along the column direction Y decreases first and then increases.

For example, FIG. 6G shows five distance values between the first border 21 and the second border 31 at different positions along the column direction Y. That is, d71, d72, d73, d74, and d75. FIG. 6G also shows five distance values between the third border 22 and the fourth border 32 at different positions along the column direction Y. That is, d81, d82, d83, d84, and d85.

In the row direction X (for example, in an order from left to right in FIG. 6G), d71 is greater than d72 and d72 is greater than d73 (d71>d72>d73), d73 is less than d74 and d74 is less than d75 (d73<d74<d75), d81 is greater than d82 and d82 is greater than d83 (d81>d82>d83), and d83 is less than d84 and d84 is less than d85 (d83<d84<d85). That is, the distance values decreases first and then increases.

In this way, the distance between the brightness centers of the first sub-pixel 2 and the second sub-pixel 3 of the same pixel 1 is small, and the distance between the brightness centers of the first sub-pixel 2 and the second sub-pixel 3 of the adjacent pixel 1 is small, so that the positions of the brightness centers of the plurality of pixels 1 in the display panel 10 may be adjusted. Therefore, when the display panel 10 uses the plurality of pixels 1 to display images, dark spots, jaggy lines, color edges, or other defects are not prone to occur in the displayed images. Moreover, in this way, areas of the first sub-pixel 2 and the second sub-pixel 3 are large, so that the aperture ratio of the display panel is large, and the display effect of the display panel is improved.

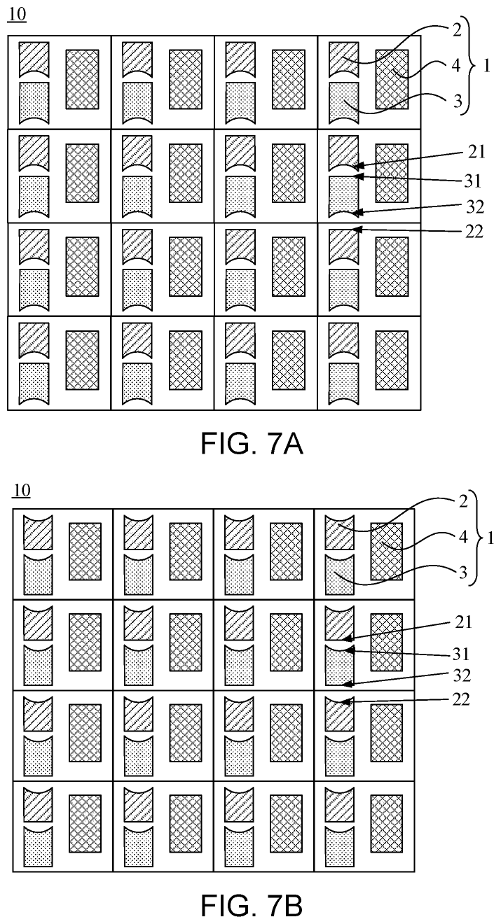

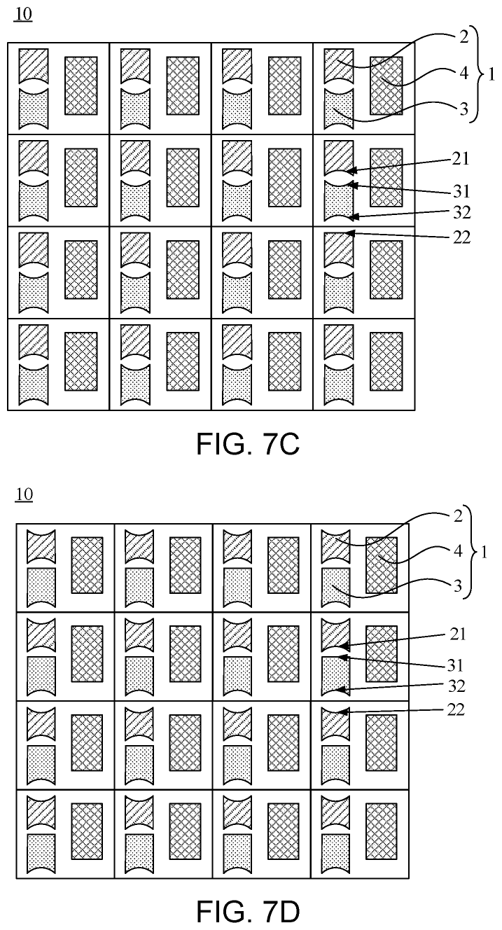

In some embodiments, as shown in FIGS. 7A to 7C, at least one of the first border 21 and the second border 31 is in a shape of an arc.

As shown in FIG. 7A, the description that “at least one of the first border 21 and the second border 31 is in a shape of an arc” may be that: the first border 21 is in a shape of an arc, and the second border 31 is not in a shape of an arc.

As shown in FIG. 7B, the description that “at least one of the first border 21 and the second border 31 is in a shape of an arc” may be that: the second border 31 is in a shape of an arc, and the first border 21 is not in a shape of an arc.

As shown in FIG. 7C, the description that “at least one of the first border 21 and the second border 31 is in a shape of an arc” may be that the first border 21 and the second border 31 are each in a shape of an arc.

Since the at least one of the first border 21 and the second border 31 is in a shape of an arc, the distance between the brightness centers of the first sub-pixel 2 and the second sub-pixel 3 can be adjusted, and the position of the brightness center of the pixel is adjusted. Therefore, when the display panel 10 uses the plurality of pixels 1 to display images, dark spots, jaggy lines, color edges, or other defects are not prone to occur in the displayed images.

In some other embodiments, as shown in FIGS. 7A, 7B, 7C and 7D, at least one of the third border 22 and the fourth border 32 is in a shape of an arc.

As shown in FIG. 7B, the description that “at least one of the third border 22 and the foul ti border 32 is in a shape of an arc” may be that the third border 22 is in a shape of an arc, and the fourth border 32 is not in a shape of an arc.

As shown in FIG. 7A, the description that “at least one of the third border 22 and the fourth border 32 is in a shape of an arc” may be that the fourth border 32 is in a shape of an arc, and the third border 22 is not in a shape of an arc.

As shown in FIG. 7D, the description that “at least one of the third border 22 and the fourth border 32 is in a shape of an arc” may be that the third border 22 and the fourth border 32 are both in a shape of an arc.

Since the at least one of the third border 22 and the fourth border 32 is in a shape of an arc, the distance between the brightness centers of the first sub-pixel 2 and the second sub-pixel 3 of two adjacent pixels 1 can be adjusted. Therefore, the positions of the brightness centers of the plurality of pixels 1 in the display panel 10 is adjusted. As a result, when the display panel 10 uses the plurality of pixels 1 to display images, dark spots, jaggy lines, color edges, or other defects are not prone to occur in the displayed images.

In yet some other embodiments, as shown in FIGS. 6A to 7D, at least one of the first border 21 and the second border 31 is in a shape of an arc, and at least one of the third border 22 and the fourth border 32 is in a shape of an arc.

The description that “at least one of the first border 21 and the second border 31 is in a shape of an arc, and at least one of the third border 22 and the fourth border 32 is in a shape of an arc” may be that, for example, one of the first border 21 and the second border 31 is in a shape of an arc, and one of the third border 22 and the fourth border 32 is in a shape of an arc. That is, the first border 21 and the third border 22 are in a shape of an arc, and the second border 31 and the fourth border 32 are not in a shape of an arc. Alternatively, the first border 21 and the fourth border 32 are in a shape of an arc, and the second border 31 and the third border 22 are not in a shape of an arc. Alternatively, the second border 31 and the third border 22 are in a shape of an arc, and the first border 21 and the fourth border 32 are not in a shape of an arc. Alternatively, the second border 31 and the fourth border 32 are in a shape of an arc, and the first border 21 and the third border 22 are not in a shape of an arc.

The description that “at least one of the first border 21 and the second border 31 is in a shape of an arc, and at least one of the third border 22 and the fourth border 32 is in a shape of an arc” may also be that, for example, the first border 21 and the second border 31 are both in a shape of an arc, and one of the third border 22 and the fourth border 32 is in a shape of an arc. That is, the first border 21, the second border 31, and the third border 22 are all in a shape of an arc, and the fourth border 32 is not in a shape of an arc. Alternatively, the first border 21, the second border 31, and the fourth border 32 are all in a shape of an arc, and the third border 22 is not in a shape of an arc.

The description that “at least one of the first border 21 and the second border 31 is in shape of an arc, and at least one of the third border 22 and the fourth border 32 is in a shape of an arc” may also be that, for example, the third border 22 and the fourth border 32 are both in a shape of an arc, and one of the first border 21 and the second border 31 is in a shape of an arc. That is, the third border 22, the fourth border 32, and the first border 21 are all in a shape of an arc, and the second border 31 is not in a shape of an arc. Alternatively, the third border 22, the fourth border 32, and the second border 31 are all in a shape of an arc, and the first border 21 is not in a shape of an arc.

The description that “at least one of the first border 21 and the second border 31 is in a shape of an arc, and at least one of the third border 22 and the fourth border 32 is in a shape of an arc” may also be that, for example, the first border 21, the second border 31, the third border 22 and the fourth border 32 are all in a shape of an arc.

In some embodiments of the present disclosure, the at least one of the first border 21 and the second border 31 is set to be in a shape of an arc, and the at least one of the third border 22 and the fourth border 32 is set to be in a shape of an arc, so that the distance between the brightness centers of the first sub-pixel 2 and the second sub-pixel 3 in the same pixel 1 can be adjusted, the distance between the brightness centers of the first sub-pixel 2 and the second sub-pixel 3 located in two adjacent pixels 1 and located in the same column can be adjusted. Therefore, the positions of the brightness centers of the plurality of pixels 1 in the display panel 10 can be adjusted. As a result, when the display panel 10 uses the plurality of pixels 1 to display images, dark spots, jaggy lines, color edges, or other defects are not prone to occur in the displayed images.

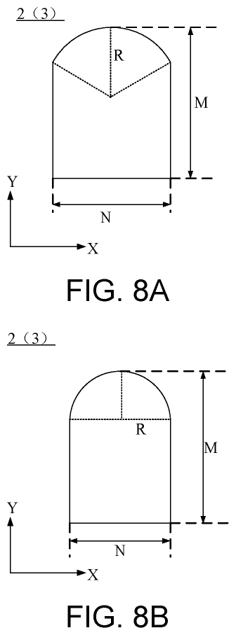

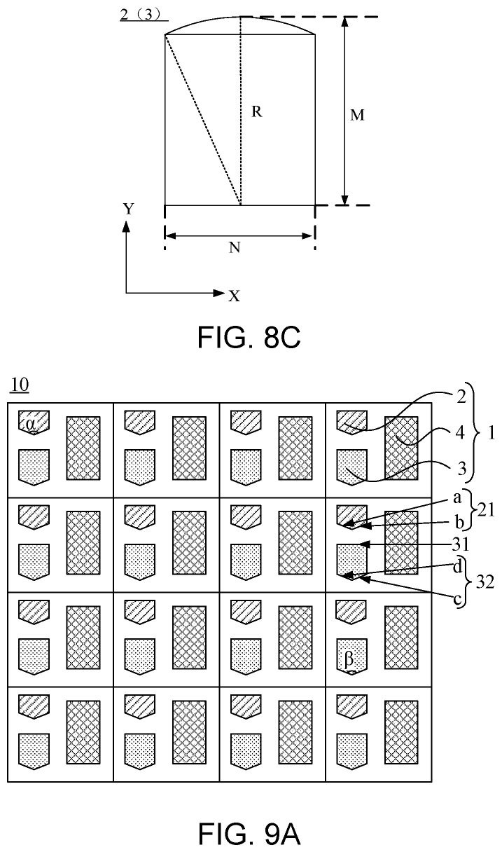

In some embodiments, as shown in FIGS. 8A to 8C, a radius R of an arc is greater than or equal to a half of a size N, in the row direction X, of a sub-pixel (e.g., a first sub-pixel 2 or a second sub-pixel 3) to which the arc belongs, and the radius R of the arc is less than or equal to a maximum size M, in the column direction Y, of the sub-pixel (the first sub-pixel 2 or the second sub-pixel 3) to which the arc belongs.

In this way, a curvature of the arc may be large, and a variation of a distance between the sub-pixel to which the arc belongs and a sub-pixel directly opposite to the arc in the column direction Y is large in the row direction X, so that a brightness center of the sub-pixel to which the arc belongs and a brightness center of the sub-pixel directly opposite to the arc can be closer to each other or farther away from each other. Therefore, the brightness center of the pixel 1 may be further adjusted, the display of the display panel is improved, and dark spots, jaggy lines, color edges, or other defects in the displayed images are ameliorated.

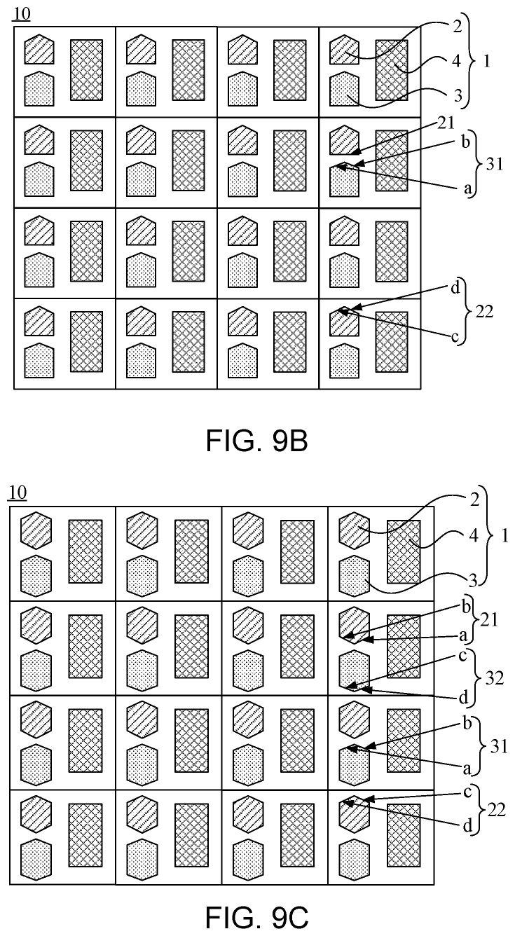

In some embodiments, as shown in FIGS. 9A to 9C, at least one of the first border 21 and the second border 31 includes a first broken line segment a and a second broken line segment b that are connected to each other. The first broken line segment a and the second broken line segment b constitute a first included angle α, and the first included angle α is greater than or equal to 90 degrees and less than or equal to 180 degrees.

As shown in FIG. 9A, the description that “at least one of the first border 21 and the second border 31 includes a first broken line segment a and a second broken line segment b that are connected to each other” may be that the first border 21 includes a first broken line segment a and a second broken line segment that are connected to each other.

As shown in FIG. 9B, the description that “at least one of the first border 21 and the second border 31 includes a first broken line segment a and a second broken line segment b that are connected to each other” may be that the second border 31 includes a first broken line segment a and a second broken line segment that are connected to each other.

As shown in FIG. 9C, the description that “at least one of the first border 21 and the second border 31 includes a first broken line segment a and a second broken line segment b that are connected to each other” may be that the first border 21 and the second border 31 each include a first broken line segment a and a second broken line segment that are connected to each other.

In this way, it is possible to adjust the position of the brightness center of the first sub-pixel 2 to which the first border 21 belongs and/or the position of the brightness center of the second sub-pixel 3 to which the second border 31 belongs, and in turn adjust the position of the brightness center of the pixel 1, and ameliorate dark spots, jaggy lines, color edges or other defects in the display images. In addition, since the first included angle α is greater than or equal to 90 degrees and less than or equal to 180 degrees, an area of the first sub-pixel 2 and/or an area of the second sub-pixel 3 can be large. Therefore, the display panel 10 has a large aperture ratio, and the display panel 10 has a good display effect.

In some other embodiments, as shown in FIGS. 9A to 9C, at least one of the third border 22 and the fourth border 32 includes a third broken line segment c and a fourth broken line segment d. The third broken line segment c and the fourth broken line segment d constitute a second included angle β, and the second included angle β is greater than or equal to 90 degrees and less than or equal to 180 degrees.

As shown in FIG. 9B, the description that “at least one of the third border 22 and the fourth border 32 includes a third broken line segment c and a fourth broken line segment d that are connected to each other” may be that the third border 22 includes a third broken line segment c and a fourth broken line segment d that are connected to each other.

As shown in FIG. 9A, the description that “at least one of the third border 22 and the fourth border 32 includes a third broken line segment c and a fourth broken line segment d that are connected to each other” may be that the fourth border 32 includes a third broken line segment c and a fourth broken line segment d that are connected to each other.

As shown in FIG. 9C, the description that “at least one of the third border 22 and the fourth border 32 includes a third broken line segment c and a fourth broken line segment d that are connected to each other” may be that the third border 22 and the fourth border 32 each include a third broken line segment c and a fourth broken line segment d that are connected to each other.

In this way, by adjusting the shape of the third border 22 and/or the shape of the fourth border 32, it is possible to adjust the position of the brightness center of the first sub-pixel 2 to which the third border 22 belongs and/or the position of the brightness center of the second sub-pixel 3 to which the fourth border 32 belongs, and in turn adjust the position of the brightness center of the pixel 1, and ameliorate dark spots, jaggy lines, color edges or other defects in the displayed images. In addition, since the second included angle β is greater than or equal to 90 degrees and less than or equal to 180 degrees, the area of the first sub-pixel 2 and/or the area of the second sub-pixel 3 is large. Therefore, the aperture ratio of the display panel 10 is large, and the display effect of the display panel 10 is improved.

In yet some other embodiments, as shown in FIGS. 9A to 9C, at least one of the first border 21 and the second border 31 includes a first broken line segment a and a second broken line segment b that are connected to each other, the first broken line segment a and the second broken line segment b constitute a first included angle α, and the first included angle α is greater than or equal to 90 degrees and less than or equal to 180 degrees. In this case, at least one of the third border 22 and the fourth border 32 includes a third broken line segment c and a fourth broken line segment d that are connected to each other. The third broken line segment c and the fourth broken line segment d constitute a second included angle β, and the second included angle β is greater than or equal to 90 degrees and less than or equal to 180 degrees.

In some examples, the first border 21 includes a first broken line segment a and a second broken line segment b that are connected to each other, and the third border 22 includes a third broken line segment c and a fourth broken line segment d that are connected to each other.

In some other examples, the first border 21 includes a first broken line segment a and a second broken line segment b that are connected to each other, and the fourth border 32 includes a third broken line segment c and a fourth broken line segment d that are connected to each other.

In yet some other examples, the second border 31 includes a first broken line segment a and a second broken line segment b that are connected to each other, and the third border 22 includes a third broken line segment c and a fourth broken line segment d that are connected to each other.

In yet some other examples, the second border 31 includes a first broken line segment a and a second broken line segment b that are connected to each other, and the fourth border 32 includes a third broken line segment c and a fourth broken line segment d that are connected to each other.

In yet some other examples, the first border 21 and the second border 31 each include a first broken line segment a and a second broken line segment b that are connected to each other, and the third border 22 includes a third broken line segment c and a fourth broken line segment d that are connected to each other.

In yet some other examples, the first border 21 and the second border 31 each include a first broken line segment a and a second broken line segment b that are connected to each other, and the fourth border 32 includes a third broken line segment c and a fourth broken line segment d that are connected to each other.

In yet some other examples, the first border 21 includes a first broken line segment a and a second broken line segment b that are connected to each other, and the third border 22 and the fourth border 32 each include a third broken line segment c and a fourth broken line segment d that are connected to each other.

In yet some other examples, the second border 31 includes a first broken line segment a and a second broken line segment b that are connected to each other, and the third border 22 and the fourth border 32 each include a third broken line segment c and a fourth broken line segment d that are connected to each other.

In yet some other examples, the first border 21 and the second border 31 each include a first broken line segment a and a second broken line segment b that are connected to each other, and the third border 22 and the fourth border 32 each include a third broken line segment c and a foul broken line segment d that are connected to each other.

In this way, the position of the brightness center of the first sub-pixel 2 and the position of the brightness center of the second sub-pixel 3 are further adjusted, so that the brightness center of the pixel 1 is adjusted, and dark spots, jaggy lines, color edges or other defects in the display images are ameliorated. In addition, since the first included angle α is an obtuse angle and the second included angle β is also an obtuse angle, the area of the first sub-pixel 2 and/or the area of the second sub-pixel 3 may be large. Therefore, the aperture ratio of the display panel 10 is large, and the display effect of the display panel is good.

In some embodiments, as shown in FIGS. 7A to 7D, at least one of the first border 21 and the third border 22 is recessed towards an interior of the first sub-pixel 2.

As shown in FIG. 7A, the description that “at least one of the first border 21 and the third border 22 is recessed towards an interior of the first sub-pixel 2” may be that the first border 21 is recessed towards the interior of the first sub-pixel 2.

As shown in FIG. 7B, the description that “at least one of the first border 21 and the third border 22 is recessed towards an interior of the first sub-pixel 2” may be that the third border 22 is recessed towards the interior of the first sub-pixel 2.

As shown in FIG. 7D, the description that “at least one of the first border 21 and the third border 22 is recessed towards an interior of the first sub-pixel 2” may be that the first border 21 and the third border 22 are recessed towards the interior of the first sub-pixel 2.

In some embodiments of the present disclosure, since the at least one of the first border 21 and the third border 22 is recessed towards the interior of the first sub-pixel 2, it may be possible to adjust the position of the brightness center of the first sub-pixel 2, and in turn adjust the position of the brightness center of the pixel 1, and ameliorate dark spots, jaggy lines, color edges, or other defects in the images displayed by the display panel 10.

In some other embodiments, as shown in FIGS. 7B to 7D, at least one of the second border 31 and the fourth border 32 is recessed towards an interior of the second sub-pixel 3.

As shown in FIG. 7B, the description that “at least one of the second border 31 and the fourth border 32 is recessed towards an interior of the second sub-pixel 3” may be that the second border 31 is recessed towards the interior of the second sub-pixel 3.

As shown in FIG. 7D, the description that “at least one of the second border 31 and the fourth border 32 is recessed towards an interior of the second sub-pixel 3” may be that the fourth border 32 is recessed towards the interior of the second sub-pixel 3.

As shown in FIG. 7C, the description that “at least one of the second border 31 and the fourth border 32 is recessed towards an interior of the second sub-pixel 3” may be that the second border 31 and the fourth border 32 are recessed towards the interior of the second sub-pixel 3.

In some embodiments of the present disclosure, since the at least one of the second border 31 and the fourth border 32 is recessed towards the interior of the second sub-pixel 3, it may be possible to adjust the position of the brightness center of the second sub-pixel 3, and in turn adjust the position of the brightness center of the pixel 1. As a result, when the display panel displays images, dark spots, jaggy lines, color edges, or other defects are not prone to occur in the displayed images.

In yet some other embodiments, at least one of the first border 21 and the third border 22 is recessed towards an interior of the first sub-pixel 2, and at least one of the second border 31 and the fourth border 32 is recessed towards an interior of the second sub-pixel 3, In some examples, the first border 21 may be recessed towards the interior of the first sub-pixel 2, and the second border 31 may be recessed towards the interior of the second sub-pixel 3.

In some other examples, the first border 21 may be recessed towards the interior of the first sub-pixel 2, and the fourth border 32 may be recessed towards the interior of the second sub-pixel 3.

In yet some other examples, the third border 22 may be recessed towards the interior of the first sub-pixel 2, and the second border 31 may be recessed towards the interior of the second sub-pixel 3.

In yet some other examples, the third border 22 may be recessed towards the interior of the first sub-pixel 2, and the fourth border 32 may be recessed towards the interior of the second sub-pixel 3.

In yet some other examples, the first border 21 and the third border may be recessed towards the interior of the first sub-pixel, and the second border may be recessed towards the interior of the second sub-pixel.

In yet some other examples, the first border 21 and the third border may be recessed towards the interior of the first sub-pixel, and the fourth border may be recessed towards the interior of the second sub-pixel.

In yet some other examples, the second border and the fourth border may be recessed towards the interior of the second sub-pixel, and the first border may be to recessed towards the interior of the first sub-pixel.

In yet some other examples, the second border and the fourth border may be recessed towards the interior of the second sub-pixel, and the third border may be recessed towards the interior of the first sub-pixel.

In yet some other examples, the first border 21 and the third border 22 may be recessed towards the interior of the first sub-pixel 2, and the second border 31 and the fourth border 32 may be recessed towards the interior of the second sub-pixel 3.

In this way, the position of the brightness center of the first sub-pixel 2 and the position of the brightness center of the second sub-pixel 3 may be adjusted, and in turn the brightness center of the pixel 1 is adjusted. As a result, when the display panel 10 displays images, dark spots, jaggy lines, color edges or other defects are not prone to occur in the displayed images.

In yet some other embodiments, as shown in FIG. 6A, at least one of the first border 21 and the third border 22 may also be protrude towards an outside of the first sub-pixel 2. In this way, it is possible to adjust the brightness center of the first sub-pixel 2, and in turn adjust the brightness center of the pixel 1, so that when the display panel displays images, dark spots, jaggy lines, color edges or other defects are not prone to occur in the display images.

In yet some other embodiments, as shown in FIG. 6A, at least one of the second border 31 and the fourth border 32 may also be protrude towards an outside of the second sub-pixel 3. In this way, itis possible to adjust the brightness center of the second sub-pixel 3, and in turn adjust the brightness center of the pixel 1, so that when the display panel 10 displays images, dark spots, jaggy lines, color edges or other defects are not prone to occur in the display images.

In yet some other embodiments, as shown in FIG. 4, at least one of the first border 21 and the third border 22 protrudes towards the outside of the first sub-pixel 2, and at least one of the second border 31 and the fourth border 32 protrudes towards the outside of the second sub-pixel 3. In this way, the brightness centers of the first sub-pixel 2 and the second sub-pixel 3 may be adjusted, and the brightness center of the pixel 1 is further adjusted, so that when the display panel displays images, dark spots, jaggy lines, color edges or other defects are not prone to occur in the display images.

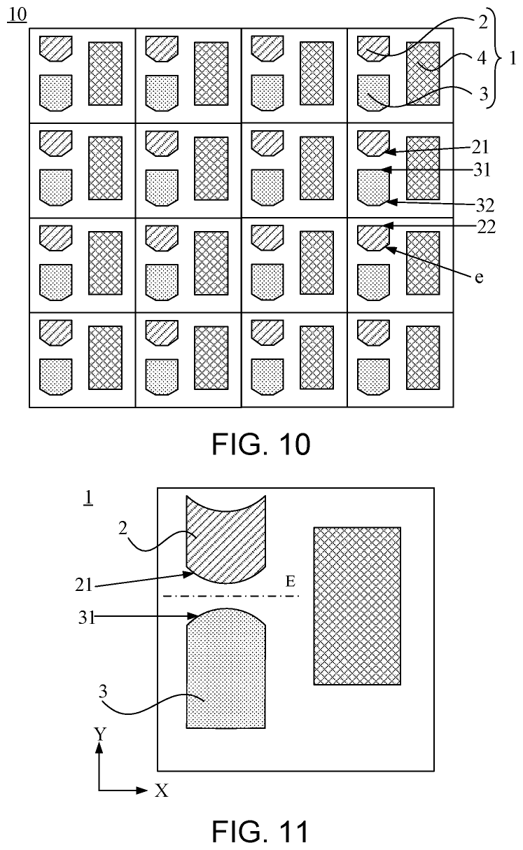

In some embodiments, as shown in FIG. 10, at least one of the first border 21, the second border 31, the third border 22, and the fourth border 32 is a broken line, and the broken line includes at least three broken line segments connected in sequence.

The description that “at least one of the first border 21, the second border 31, the third border 22, and the fourth border 32 is a broken line” may be that only one of the first border 21, the second border 31, the third border 22, and the fourth border 32 is a broken line, or only two of the first border 21, the second border 31, the third border 22, and the fourth border 32 are broken lines, or three of the first border 21, the second border 31, the third border 22, and the fourth border 32 are broken lines, or all of the first border 21, the second border 31, the third border 22, and the fourth border 32 are broken lines.

It should be noted that FIG. 10 only shows that the first border 21 and the fourth border 32 are each a broken line, and the broken line includes three broken line segments e connected in sequence. For example, the broken line may further include four broken line segments connected in sequence, five broken line segments connected in sequence, and the like.

In some embodiments of the present disclosure, since the at least one of the first border 21, the second border 31, the third border 22, and the fourth border 32 is a broken line, the brightness center of the first sub-pixel 2 and/or the brightness center of the second sub-pixel 3 can be adjusted. Therefore, the brightness center of the pixel 1 can be adjusted, and dark spots, jaggy lines, color edges or other defects in the images displayed by the display panel are ameliorated. In addition, light-emitting areas of the first sub-pixel 2 and the second sub-pixel 3 may be increased, the aperture ratio is improved, and the display effect of the display panel 10 is enhanced.

In some embodiments, as shown in FIG. 11, the first border 21 and the second border 31 are symmetrical with respect to a first reference line E extending along the row direction X. In this way, the design of edges of the first sub-pixel 2 and the second sub-pixel 3 is simple and convenient, and the manufacturing is convenient, which is conducive to improving the manufacturing efficiency of the display panel 10.

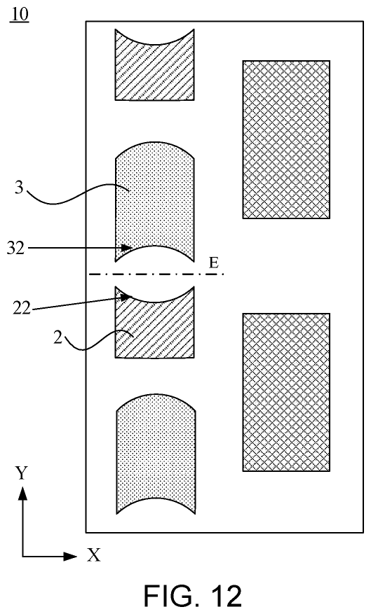

In some other embodiments, as shown in FIG. 12, the third border 22 and the fourth border 32 are symmetrical with respect to another first reference line E extending along the row direction X. In this way, the design of the edges of the first sub-pixel 2 and the edge of the second sub-pixel 3 is simple and convenient, and the manufacturing is convenient, which is conducive to improving the manufacturing efficiency of the display panel 10.

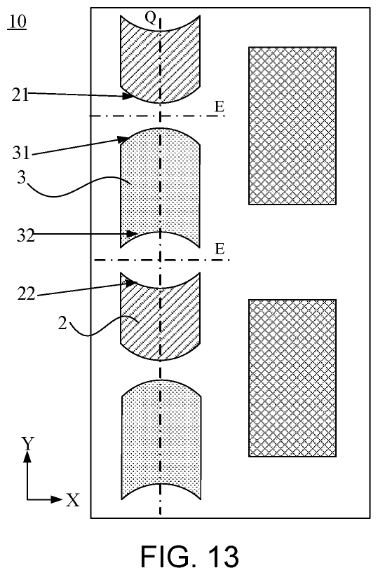

In yet some other embodiments, as shown in FIG. 13, e first border 21 and the second border 31 are symmetrical with respect to the first reference line E extending in the row direction X, and the third border 22 and the fourth border 32 are symmetrical with respect to the another first reference line E extending in the row direction X. In this way, the design of the edges of the first sub-pixel 2 and the edge of the second sub-pixel 3 is further simple and convenient, and the manufacturing is convenient, which is conducive to improving the manufacturing efficiency of the display panel 10.

In some embodiments, as shown in FIG. 13, at least one of the first border 21, the second border 31, the third border 22, and the fourth border 32 is an axisymmetric pattern whose symmetry axis Q extends along the column direction Y. In this way, at least one of the first sub-pixel 2 and the second sub-pixel 3 has a regular shape and is easy to manufacture, thereby improving the manufacturing efficiency of the display panel 10.

The description that “at least one of the first border 21, the second border 31, the third border 22, and the fourth border 32 is an axisymmetric pattern” may be that only one of the first border 21, the second border 31, the third border 22, and the fourth border 32 is an axisymmetric pattern, or two of the first border 21, the second border 31, the third border 22, and the fourth border 32 may be axisymmetric patterns, or three of the first border 21, the second border 31, the third border 22, and the fourth border 32 may be axisymmetric patterns, or all of the first border 21, the second border 31, the third border 22, and the fourth border 32 may be axisymmetric patterns.

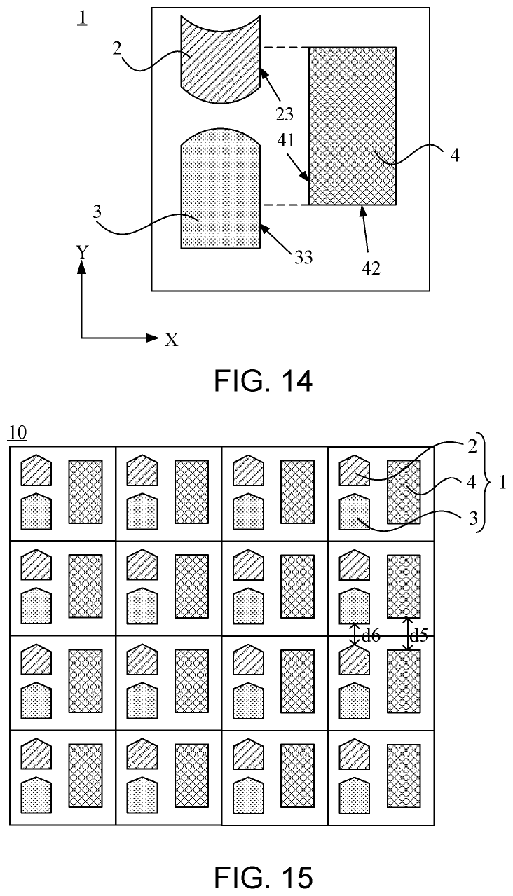

In some embodiments, as shown in FIG. 14, the first sub-pixel 2 includes a fifth border 23 that extends along the column direction Y and is proximate to the third sub-pixel 4, and the second sub-pixel 3 includes a sixth border 33 that extends along the column direction Y and is proximate to the third sub-pixel 4. The third sub-pixel 4 includes a seventh border 41 that extends along the column direction Y and is proximate to the first sub-pixel 2 or the second sub-pixel 3. In the same pixel 1, the seventh border 41 is at least partially directly opposite to at least one of the fifth border 23 and the sixth border 33 in the row direction X.

The seventh border 41 may be partially or completely directly opposite to the fifth border 23 in the row direction X. The seventh border 41 may also be partially or completely directly opposite to the sixth border 33 in the row direction X. The seventh border may also be partially directly opposite to each of the fifth border 23 and the sixth border 33 in the row direction X.

In this way, the third sub-pixel 4 is close to the first sub-pixel 2 and the second sub-pixel 3 that are located in the same pixel 1 as the third sub-pixel 4, so that the brightness center of the third sub-pixel 4 is close to the brightness centers of the first sub-pixel 2 and the second sub-pixel 3 that are located in the same pixel 1 as the third sub-pixel 4. Therefore, the brightness of the pixel 1 may be high, and the display effect of the display images of the display panel 10 is good.

In some embodiments, as shown in FIG. 14, the third sub-pixel 4 includes at least one eighth border 42 extending along the row direction X, and the at least one eighth border 42 is a straight line segment. Since the eighth border 42 is a straight line segment, the third sub-pixel 4 is in a shape of a regular pattern, and is easy to manufacture, which simplifies the manufacturing process of the display panel 10.

In some embodiments, as shown in FIG. 15, a distance between two adjacent third sub-pixels 4 is equal. In this way, the third sub-pixels 4 may be evenly distributed in the display panel 10, and the display effect of the display panel 10 is good.

In some embodiments, as shown in FIG. 15, a distance d5 between two adjacent third sub-pixels 4 is greater than a minimum distance d6 between a first sub-pixel 2 and a second sub-pixel 3 that are adjacent in a same column of sub-pixels 1. In this way, the distance between the first sub-pixel 2 and the second sub-pixel 3 can be small, and the sub-pixels in the odd-numbered column are arranged compactly, which is conducive to increasing the number of sub-pixels in the display panel 10, improving the number of pixels 1, and improving the resolution.

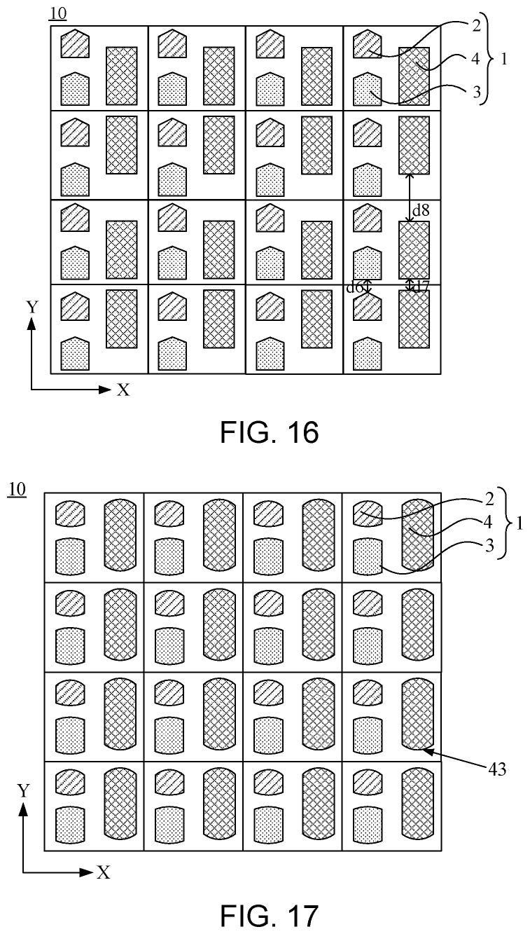

In some embodiments, as shown in FIG. 16, along the column direction Y, in the same column of sub-pixels, distances between a third sub-pixel 4 and two third sub-pixels 4 adjacent to the third sub-pixel 4 are a first distance d7 and a second distance d8, respectively. The first distance d7 is smaller than the second distance d8. The first distance d7 is less than the minimum distance between the first sub-pixel 2 and the second sub-pixel 3 that are adjacent in the same column of sub-pixels, and the second distance d8 is greater than the minimum distance d6 between the first sub-pixel 2 and the second sub-pixel 3 that are adjacent in the same column of sub-pixels.

In some embodiments, referring to FIGS. 3 and 16, along the column direction Y, two adjacent third sub-pixels 4 with a distance of the first distance d7 share one light-emitting layer 134, In this way, it may be possible to simply a design process of a mask, and in turn simplify a manufacturing process of the light-emitting layers 134 in the sub-pixels.

In some embodiments, as shown in FIG. 17, along the column direction Y, a border of the third sub-pixel 4 proximate to an adjacent third sub-pixel 4 is a ninth border 43, and distances from at least two points on the ninth border 43 to another ninth border 43 adjacent to the ninth border 43 along the column direction Y are not equal.

In some embodiments of the present disclosure, since the distances between the at least two points on the ninth border 43 and the adjacent ninth border 43 are not equal, the brightness centers of the third sub-pixels 4 are adjusted, and the brightness centers of the pixels 1 are adjusted. Therefore, when the display panel 10 displays images, dark spots, jaggy lines, color edges or other defects are not prone to occur in the displayed images.

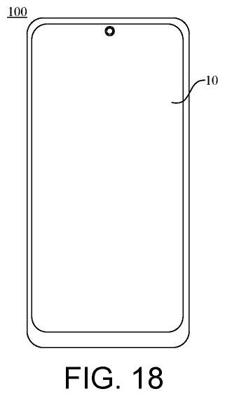

Some embodiments of the present disclosure provide a display device 100, as shown in FIG. 18, the display device 100 includes the display panel 10 according to any of the above embodiments. The display device 100 may be any component with a display function, such as a television, a digital camera, a mobile phone, a watch, a tablet computer, a notebook computer, or a navigator.

Beneficial effects that can be achieved by the display device 100 provided in the embodiments of the present disclosure are the same as the beneficial effects that can be achieved by the display panel 10 provided in the above technical solutions, and details to will not be repeated again.

The foregoing descriptions are merely specific implementations of the present disclosure, but the protection scope of the present disclosure is not limited thereto. Any changes or replacements that a person skilled in the art could conceive of within the technical scope of the present disclosure shall be inducted in the protection scope of the present disclosure. Therefore, the protection scope of the present disclosure shall be subject to the protection scope of the claims.

1. A display panel, comprising a plurality of pixels arranged in a plurality of rows and a plurality of columns, wherein
each pixel includes a first sub-pixel configured to display a first color, a second sub-pixel configured to display a second color, and a third sub-pixel configured to display a third color;
all sub-pixels included in the plurality of pixels are arranged in a plurality of columns; in an odd-numbered column of sub-pixels, first sub-pixels and second sub-pixels are alternately arranged; in an even-numbered column of sub-pixels, third sub-pixels are sequentially arranged;
wherein for a first sub-pixel and a second sub-pixel of a same pixel, along a column direction, a border of the first sub-pixel proximate to the second sub-pixel is a first border, and a border of the second sub-pixel proximate to the first sub-pixel is a second border; and distances from at least two points on the first border to the second border along the column direction are not equal.

2. The display panel according to claim 1, wherein for the first sub-pixel and the second sub-pixel of the same pixel, along the column direction, a border of the first sub-pixel away from the second sub-pixel is a third border, and a border of the second sub-pixel away from the first sub-pixel is a fourth border; and distances from at least two points on the third border to a fourth border of a second sub-pixel of an adjacent pixel along the column direction are not equal.

3. The display panel according to claim 2, wherein in a row direction, a distance between the first border and the second border along the column direction increases first and then decreases; and/or
in the row direction, a distance between the third border and the fourth border of the second sub-pixel of the adjacent pixel along the column direction increases first and then decreases.

4. The display panel according to claim 2, wherein in a row direction, a distance between the first border and the second border in the column direction decreases first and then increases; and/or
in the row direction, a distance between the third border and the fourth border of the second sub-pixel of the adjacent pixel in the column direction decreases first and then increases.

5. The display panel according to claim 3, wherein at least one of the first border and the second border is in a shape of an arc; and/or
at least one of the third border and the fourth border is in a shape of an arc.

6. The display panel according to claim 5, wherein a radius of an arc is greater than or equal to a half of a size, in the row direction, of a sub-pixel to which the arc belongs; and
the radius of the arc is less than or equal to a maximum size, in the column direction, of the sub-pixel to which the arc belongs.

7. The display panel according to claim 3 or 1, wherein at least one of the first border and the second border includes a first broken line segment and a second broken line segment that are connected to each other; the first broken line segment and the second broken line segment constitute a first included angle; and the first included angle is greater than or equal to 90 degrees and less than or equal to 180 degrees; and/or
at least one of the third border and the fourth border includes a third broken line segment and a fourth broken line segment that are connected to each other; the third broken line segment and the fourth broken line segment constitute a second included angle; and the second included angle is greater than or equal to 90 degrees and less than or equal to 184 degrees.

8. The display panel according to claim 2, wherein at least one of the first border and the third border is recessed towards an interior of the first sub-pixel; and/or
at least one of the second border and the fourth border of the second sub-pixel is recessed towards an interior of the second sub-pixel.

9. The display panel according to claim 2, wherein at least one of the first border and the third border protrudes towards an outside of the first sub-pixel; and/or
at least one of the second border and the fourth border of the second sub-pixel protrudes towards an outside of the second sub-pixel.

10. The display panel according to claim 2, wherein at least one of the first border, the second border, the third border and the fourth border is a broken line, and the broken line includes at least three broken line segments connected in sequence.

11. The display panel according to claim 2, wherein the first border and the second border are symmetrical with respect to a first reference line extending along a row direction; and/or
the third border and the fourth border are symmetrical with respect to another first reference line extending along the row direction.

12. The display panel according to claim 2, wherein at least one of the first border, the second border, the third border, and the fourth border is an axisymmetric pattern whose symmetry axis extends along the column direction.

13. The display panel according to claim 1, wherein in the same pixel, the first sub-pixel includes a fifth border extending along the column direction and proximate to the third sub-pixel, the second sub-pixel includes a sixth border extending along the column direction and proximate to the third sub-pixel, and the third sub-pixel includes a seventh border extending along the column direction and proximate to the first sub-pixel or the second sub-pixel;
in the same pixel, the seventh border is at least partially directly opposite to at least one of the fifth border and the sixth border in a row direction.

14. The display panel according to claim 1, wherein the third sub-pixel includes at least one eighth border extending along a row direction, and the at least one eighth border is a straight line segment.

15. The display panel according to claim 14, wherein a distance between two adjacent third sub-pixels along the column direction is equal.

16. The display panel according to claim 15, wherein the distance between the two adjacent third sub-pixels is greater than a minimum distance between a first sub-pixel and a second sub-pixel that are adjacent in a same column of sub-pixels.

17. The display panel according to claim 14, wherein in a same column of sub-pixels, along the column direction, distances between the third sub-pixel and two third sub-pixels adjacent to the third sub-pixel are a first distance and a second distance, respectively;
the first distance is less than the second distance; the first distance is less than a minimum distance between a first sub-pixel and a second sub-pixel that are adjacent in the same column of sub-pixels, and the second distance is greater than the minimum distance between the first sub-pixel and the second sub-pixel that are adjacent in the same column of sub-pixels.

18. The display panel according to claim 17, wherein two adjacent third sub-pixels with a distance of the first distance along the column direction share one light-emitting layer.

19. The display panel according to claim 1, wherein
along the column direction, a border of the third sub-pixel proximate to another third sub-pixel adjacent to the third sub-pixel is a ninth border; and distances from at least two points on the ninth border to another ninth border adjacent to the ninth border along the column direction are not equal.

20. A display device, comprising:
the display panel according to claim 1.
